(19) United States
(12) Patent Application Publication
(10) Pub. No.: US 2013/0009668 A1
(43) Pub. Date: Jan. 10, 2013

(54) 4-TERMINAL PIEZOELECTRONIC TRANSISTOR (PET)

(75) Inventors: Bruce G. Elmegreen, Goldens Bridge, NY (US); Glenn J. Martyna, Croton on Hudson, NY (US); Dennis M. Newns, Yorktown Heights, NY (US); Stephen Rossnagel, Pleasantville, NY (US); Paul M. Solomon, Yorktown Heights, NY (US)

(73) Assignee: International Business Machines Corporation, Armonk, NY (US)

(21) Appl. No.: 13/176,880

(22) Filed: Jul. 6, 2011

(51) Int. Cl. H01L 25/00; H01C 7/10; H01L 41/22

(52) U.S. Cl. 326/102; 29/25.35; 338/20

(57) ABSTRACT

A 4-terminal piezoelectronic transistor (PET) which includes a piezoelectric (PE) material disposed between first and second electrodes; an insulator material disposed on the second electrode; a third electrode disposed on the insulator material and a piezoresistive (PR) material disposed between the third electrode and a fourth electrode. An applied voltage across the first and second electrodes causing a pressure from the PE material to be applied to the PR material through the insulator material, the electrical resistance of the PR material being dependent upon the pressure applied by the PE material. The first and second electrodes are electrically isolated from the third and fourth electrodes. Also disclosed are logic devices fabricated from 4-terminal PETs and a method of fabricating a 4-terminal PET.

### BACKGROUND

The present invention relates to semiconductor devices and, more particularly, relates to a piezoelectronic transistor device having low power switching.

The standard CMOS (complementary metal oxide semiconductor) switching device in computers, the FET field effect transistor, cannot operate well below approximately 1 Volt, a threshold which has now been reached. Switching power cannot be further reduced by size scaling. This breakdown of Moore's Law voltage scaling has prevented increases in computer clock frequency since 2003. There is a need for a low-power switch to enable further voltage and power reductions to maintain the Moore's Law performance improvement with scaling. A successful low power switch would have broad implications for increasing speed/reducing power consumption for systems from the scale of portable electronics to supercomputers.

The piezoelectronic transistor (PET) switch has been proposed as a potential solution to the switching power problem on the basis of simulation and modeling studies. The PET is a so-called transduction device, in which electrical input is converted to nonelectrical form during the switching process. The PET has three terminals-drive, common, and sense. An input voltage applied between drive and common terminals of a piezoelectric (PE) crystal causes a displacement which acts on a selected piezoresistive (PR) material causing a pressure-induced insulator-to-metal transition. The PR “channel” material then provides a conducting path between common and sense terminals. The input voltage-to-force transduction is done by a high-performance relaxor PE.

### BRIEF SUMMARY

The various advantages and purposes of the exemplary embodiments as described above and hereafter are achieved by providing, according to a first aspect of the exemplary embodiments, a 4-terminal piezoelectronic transistor (PET) which includes a piezoelectric (PE) material disposed between first and second electrodes; an insulator material disposed on the second electrode; a third electrode disposed on the insulator material; and a piezoresistive (PR) material disposed between the third electrode and a fourth electrode. An applied voltage across the first and second electrodes causes a pressure from the PE material to be applied to the PR material through the insulator material, the electrical resistance of the PR material being dependent upon the pressure applied by the PE material.

According to a second aspect of the exemplary embodiments, there is provided logic device which includes a plurality of 4-terminal piezoelectronic transistor (PET) devices coupled together to form the logic device. Each 4-terminal PET includes a piezoelectric (PE) material disposed between first and second electrodes; an insulator material disposed on the second electrode; a third electrode disposed on the insulator material; and a piezoresistive (PR) material disposed between the third electrode and a fourth electrode An applied voltage across the first and second electrodes causes a pressure from the PE material to be applied to the PR material through the insulator material, the electrical resistance of the PR material being dependent upon the pressure applied by the PE material. The first and second electrodes are electrically isolated from the third and fourth electrodes.

According to a third aspect of the exemplary embodiments, there is provided a method of forming a 4-terminal piezoelectronic transistor (PET). The method includes forming a first stack of materials which, includes forming a first electrode; forming a piezoelectric (PE) material over the first electrode; forming a second electrode over the PE material. The method further includes forming a second stack of materials which includes forming an insulator material over the second electrode; forming a third electrode over the insulator material; forming a piezoresistive (PR) material over the third electrode; and forming a fourth electrode over the PR material.

### BRIEF DESCRIPTION OF SEVERAL VIEWS OF THE DRAWINGS

The features of the exemplary embodiments believed to be novel and the elements characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1A is a cross-sectional view of a prior art 3-terminal piezoelectronic transistor (3-terminal PET) and FIG. 1B is a circuit symbol for the 3-terminal PET.

FIG. 2A is a cross-sectional view of a 4-terminal piezoelectronic transistor (4-terminal PET) and FIG. 2B is a circuit symbol for the 4-terminal PET.

FIG. 3A is a circuit diagram for an inverter including a plurality of 4-terminal PETs and FIG. 3B is a circuit symbol for the inverter circuit.

FIG. 4A is a circuit diagram for a non-inverter including a plurality of 4-terminal PETs and FIG. 4B is a circuit symbol for the non-inverter circuit.

FIG. 5 is a circuit diagram for a NAND gate including a plurality of 4-terminal PETs.

FIG. 6 is a circuit diagram for a flip-flop including a plurality of 4-terminal PETs.

FIG. 7 is a circuit diagram for a memory cell including a plurality of 4-terminal PETs.

FIG. 8 is a circuit diagram for a memory cell with write enable including a plurality of 4-terminal PETs.

FIG. 9A is a circuit diagram for a logic block including a plurality of 4-terminal PETs and FIG. 9B is circuit diagram for two logic blocks with power supplies coupled together in series.

FIGS. 10 to 26 are illustrations depicting a method for fabricating a 4-terminal PET wherein the “A” Figure is a top view and the “B” Figure is a cross-sectional view and wherein:

FIGS. 10A and 10B illustrate a first level of metallization for forming a first electrode;

FIGS. 11A and 11B illustrate forming a PE layer on the first electrode;

FIGS. 12A and 12B illustrate depositing amorphous silicon;

FIGS. 13A and 13B illustrate a second level of metallization for forming a second electrode and wiring line to connect the first electrode;

FIGS. 14A and 14B illustrate depositing additional amorphous silicon;

FIGS. 15A and 15B illustrate forming an insulator in contact with the second electrode;

FIGS. 16A and 16B illustrate forming vias in contact with the second electrode and the wiring line that connects to the first electrode;

FIGS. 17A and 17B illustrate removing excess amorphous silicon;

FIGS. 18A and 18B illustrate forming a high yield strength material;

FIGS. 19A and 19B illustrate forming a third level of metallization for the third electrode and wiring lines that connect the first electrode and second electrode;

FIGS. 20A and 20B illustrate depositing additional amorphous silicon;

FIGS. 21A and 21B illustrate forming a PR material in contact with the third electrode;

FIGS. 22A and 228 illustrate forming a fourth level of metallization for the fourth electrode;

FIGS. 23A and 23B illustrate depositing additional high strength yield material;

FIGS. 24A and 24B illustrate forming via openings in the high strength yield material;

FIGS. 25A and 25B illustrate forming contacts to contact the first, second, third and fourth electrodes; and

FIGS. 26A and 26B illustrate removing the amorphous silicon from the 4-terminal PET.

### DETAILED DESCRIPTION

A piezoresistive material in the present context is a material that changes resistivity with applied mechanical stress so as to transition from an insulator to a conductor. A piezoelectric material is a material that may either expand or contract when an electric potential is applied across the piezoelectric material.

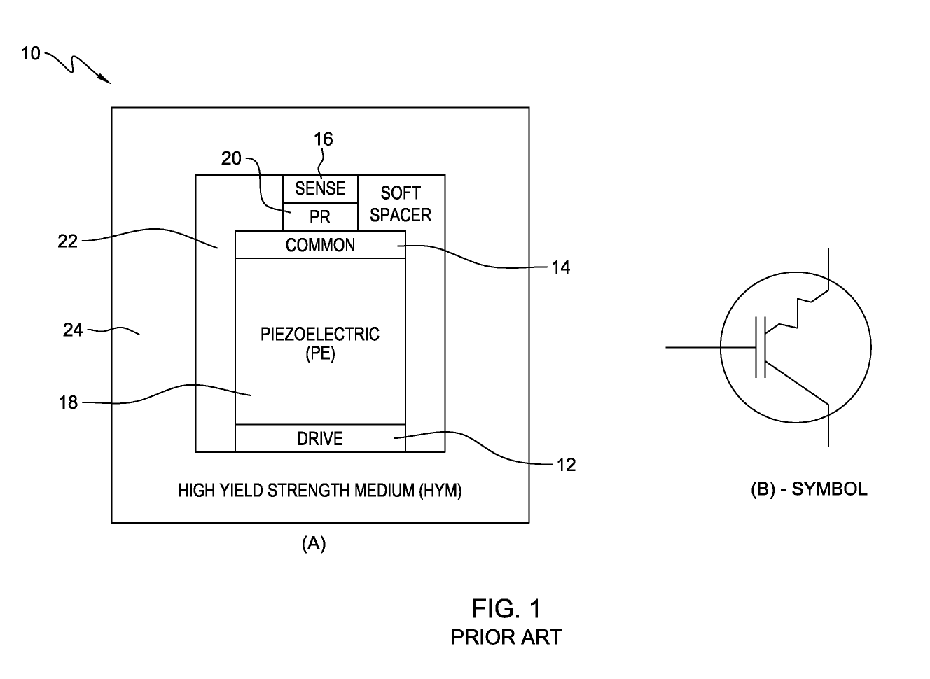

Referring now to the Figures in more detail, illustrated in FIG. 1A is a prior art 3-terminal PET. The 3-terminal PET 10 has three terminals: a drive terminal 12, a common terminal 14 and a sense terminal 16. Disposed between the drive terminal 12 and the common terminal 14 is a piezoelectric (PE) crystal material 18 and disposed between the common terminal 14 and sense terminal 16 is a piezoresistive (PR) material 20. An input voltage between the drive terminal 12 and the common terminal 14 applies a voltage to the PE crystal material 18 to cause an expansion and displacement of the PE crystal material 18 which acts on the PR material 20. The induced pressure from the PE crystal material 18 causes a continuous insulator-to-metal transition so that the PR material 20 then provides a conducting path between the common terminal 14 and the sense terminal 16. The 3-terminal PET 10 further includes a soft spacer 22 and a high yield strength material 24 which surrounds the individual components of the 3-terminal PET 10. The high yield strength material 24 is present to ensure that the PE crystal material 18 displacement is transmitted to the PR material 20 rather than the surrounding medium.

An electrical symbol for the 3-terminal PET is shown in FIG. 1B.

There are at least two problems with the 3-terminal PET which may be solved by the exemplary embodiments.

For the PE material to act as a piezoelectric actuator that converts voltage applied across it into physical displacement of its surface, the PE material needs to be poled. Poling is a process by which the dipoles that make up the PE crystal material may be aligned to impart directionality to the PE crystal material. Poling breaks the symmetry so a particular polarity of voltage across the PE results in, say, a positive strain. Poling (a) may be done by applying an electric field across the PE, or b) may arise from asymmetry in the PE film growth mode and electrodes present.

For a 3-terminal PET, complementary PET (CPET) logic requires PE films to be polable in both directions, producing PET's of two types, turned on by noninverted and by inverted input polarities respectively. However bidirectional poling requires significant ancillary circuitry to implement electrically, an undesirable complication to CPET logic. If the poling is intrinsic to the growth mode, it is difficult to get bidirectional poling.

CPET circuit fabrication therefore lacks a simple, cheap way to achieve the required bidirectional poling.

The operation of PE elements may be unipolar. That is, the electric field if nonzero is always applied in the same direction so as to enhance the poling. Unipolar operation prevents depolarization and enhances lifetime of the PET from certain forms of degradation. 3-terminal PET circuits do not always maintain unipolar operation.

The exemplary embodiments include adding an extra terminal to the 3-terminal PET in order to electrically insulate the output from the input. The addition of the fourth terminal powerfully enhances the logic capability of the PET since now the input and output terminals are completely isolated from each other, simply enabling configurations which otherwise need greatly increased circuit complexity and increased power dissipation. Examples of this are replacement of the two-transistor CMOS pass gate with a single 4-terminal PET, non-inverting buffers and logic circuits, and connection of blocks of logic operating with different voltage references. These enabling configurations also solve the poling problem of the 3-terminal PET, and in particular enable unipolar operation of the 3-terminal PET NAND since now device connections can be arranged such that the voltage across the input terminals is always unidirectional. This allows the use of unidirectional poling, for example, built in by asymmetry in the PE film growth mode and electrodes present.

The additional complication of having a PET device with four terminals is more than compensated by the inherent advantages of a totally isolated input and output and of fully resolving the poling and unipolarity issues.

In the exemplary embodiments, the common electrode of the 3-terminal PET is split into two distinct metal layers separated by an insulator which may be denoted as the Drive − and Sense 1 terminals. The 3-terminal PET drive terminal may be denoted as Drive + in the 4-terminal PET while the Sense terminal of the 3-terminal PET may be relabeled as Sense 2. The insulator separating the Drive − and Sense 1 terminals preferably has a relatively high Young's modulus, as in the range 60-250 GPa, and a relatively low dielectric constant, say in the range 4-12, and a high breakdown field.

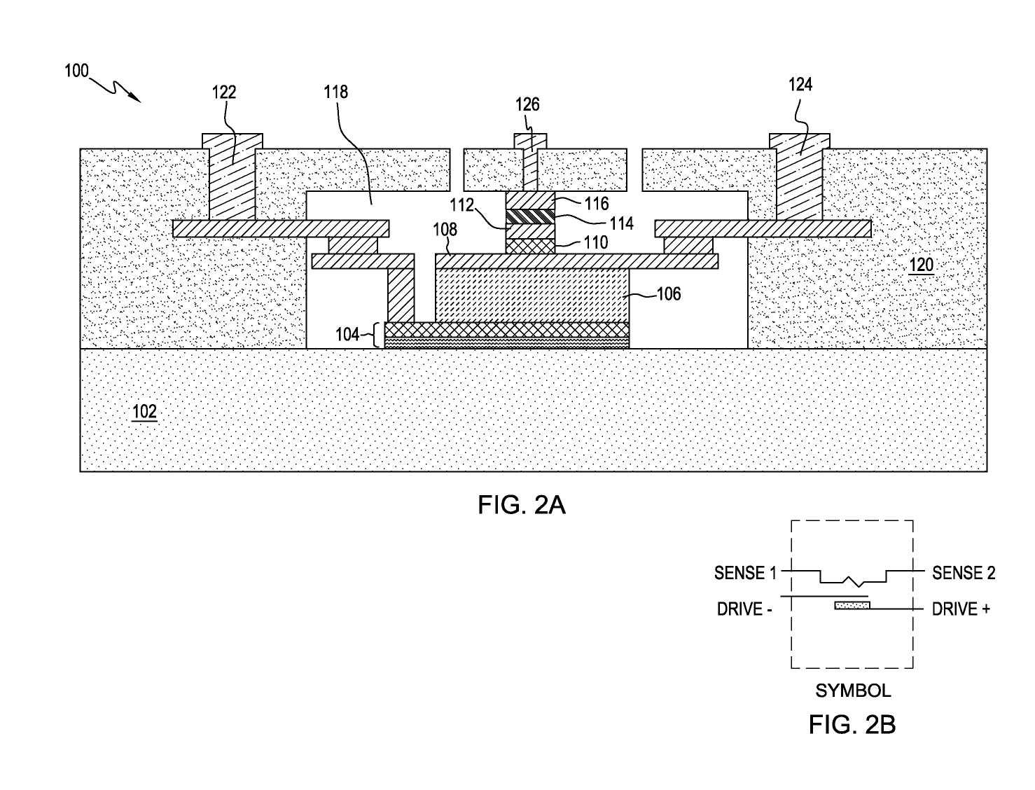

Referring now to FIG. 2A, there is illustrated an exemplary embodiment of a 4-terminal PET 100 which may be fabricated on any semiconductor substrate 102 including, but not limited to, silicon, silicon germanium, germanium, a III-V compound semiconductor, or a II-VI compound semiconductor. The semiconductor substrate may be a semiconductor on insulator (SOI) or a bulk semiconductor substrate.

The 4-terminal PET may include a first Drive electrode 104, a PE material 106 and a second Drive electrode 108. The polarity of the first and second Drive electrodes 104, 108 preferably should match the poling direction of the PE material 106. It will be assumed that the PE material 106 will be poled such that the first Drive electrode 104 may be denoted as Drive+ and the second Drive electrode 108 may be denoted as Drive−. When voltage is applied across the Drive+ electrode 104 and the Drive − electrode 108 with a polarity that matches that of the Drive+ and Drive− electrodes 104, 108, the PE material 106 will undergo a positive (expansive) displacement.

The poling of the PE, for example, implemented as part of the asymmetric growth mechanism and electrode configuration, will be uniformly the same for all 4-terminal PET devices 100 fabricated. It will be assumed that the Drive + electrode 104 being positive expands the PE perpendicular to the stack. The opposite situation requires some reversals of polarity or drive connections.

The remainder of the discussion of the exemplary embodiments assumes that the polarity of the Drive+ and Drive− electrodes 104, 108 is as shown in FIG. 2A but that in other exemplary embodiments, the polarity may be reversed and these other exemplary embodiments are to be considered within the scope of the present invention.

Further included within the 4-terminal PET is an insulator 110 which may separate the Sense 1 electrode 112 from the Drive− electrode 108. The insulator 110 may be, for example, silicon dioxide (SiO₂) or silicon nitride (Si₃N₄). There is also a PR material 114 stacked on the Sense 1 electrode 112 followed by a Sense 2 electrode 116.

The lateral dimension of the insulator 110, Sense 1 electrode 112, PR material 114 and Sense 2 electrode 116 may be much smaller than the lateral dimension of the Drive+ electrode 104, PE material 106 and Drive− electrode 108. For example, for purposes of illustration and not limitation, at 20 nm (nanometer) litho scale such lateral dimensions may be 200 to 20 nm for the PR material 114 and 2000 to 100 nm for the PE. The lateral dimension of the PE material 106 preferably is larger than the lateral dimension of the PR material 114 in order to enhance the pressure in the PR material 114.

In the exemplary embodiments, the 4-terminal PET includes a high yield strength material 120 such as silicon dioxide (SiO₂) or silicon nitride (Si₃N₄) which surrounds and encapsulates all of the components of the 4-terminal PET 100, namely, the Drive+ electrode 104, PE material 106, Drive− electrode 108, insulator 110, Sense 1 electrode 112, PR material 114 and Sense 2 electrode 116. Preferably, there is a gap or vacant space 118 between the foregoing components of the 4-terminal PET 100 and the high yield material 120. The gap is preferable as it increases freedom of mechanical displacement of elements 108, 110, 112 and 114.

The 4-terminal PET 100 may include vias and contacts for connecting the various electrodes of the 4-terminal PET 100. Thus, as shown in FIG. 2A, contact 122 makes contact with Drive+ electrode 104, contact 124 makes contact with Drive− electrode 108 and contact 126 makes contact with Sense 2 electrode 116. Not shown in FIG. 2A is a fourth contact that would make contact with Sense 1 electrode 112.

A circuit symbol for the 4-terminal PET is shown in FIG. 2B.

The electrodes in the 4-terminal PET may include materials such as strontium ruthenium oxide (SrRuO₃(SRO)), platinum (Pt), tungsten (W) or other suitable mechanically hard conducting materials. The PE may consist of a relaxor piezoelectric such as PMN-PT (lead magnesium niobate-lead titanate) or PZN-PT (lead zinc niobate-lead titanate) or other PE materials typically made from perovskite titanates. Such PE materials have a large value of displacement/V d33, e.g. d33=2500 pm/V, support a relatively high piezoelectric strain (˜1%), and have a relatively high endurance, making them ideal for the PET application. The PE could also consist of another material such as PZT (lead zirconate titanate). The PR is a material which undergoes an insulator-to-metal transition under a relatively low pressure in a range such as 0.4-3.0 GPa. Some examples of PR material are samarium selenide (SmSe), thulium telluride (TmTe), nickel disulfide/diselenide (Ni(SxSe1-x)₂), vanadium oxide (V₂O₃) doped with a small percentage of Cr, calcium ruthenium oxide (Ca₂RuO₄), etc. At 20 nm lithographic spacing, for purposes of illustration and not limitation, exemplary dimensions of the PET stack are PE height 80 nm, PE width 60 nm, PR height 2-5 nm, PR width 20 nm, metal layer thickness 5-15 nm. The foregoing dimensions may be reduced by scaling and may also be increased by an order of magnitude if desired.

The mode of operation of the 4-terminal PET is as follows. The input voltage between Drive+ electrode 104 and Drive − electrode 108 may be always positive or zero. When it is zero, the PE material 106 has no displacement and the PR material 114 is uncompressed, giving it a high electrical resistance such that the 4-terminal PET 100 is “off”. When a significant positive voltage is applied to the Drive + electrode 104 relative to the Drive − electrode 108, the PE material 106 develops a positive strain. That is, the PE material 106 expands upwards along the axis perpendicular to the stack. The upward expansion of the PE material 106 tries to compress the high Young's modulus insulator 110, but the main effect is to compress the more compressible PR material 110. The compressive action is effective because the surrounding high yield strength material 120 strongly constrains the relative motion of the top of the Sense 2 electrode 116 and the bottom of the Drive + electrode 104. The combined effect of the mechanical compression of the PR material 114 by the constrained stack and the PR material 114 piezoresistive response is to lower the Sense 1 electrode-Sense 2 electrode impedance by 3-5 orders of magnitude under conditions where the input voltage is the designed line voltage VDD. The PET switch is now “on”.

### Examples Illustrating Advantages of the Exemplary Embodiments

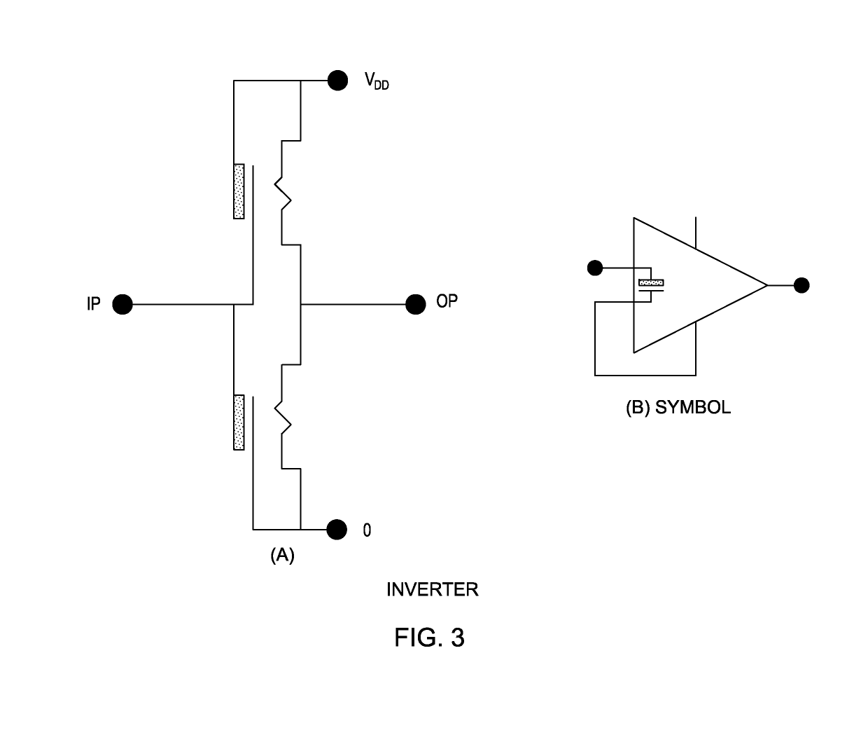

Examples of the circuits for which the 4-terminal PET may be suitable are shown in FIGS. 3 to 9.

FIG. 3A shows a PET inverter, which has broadly similar design to a CMOS inverter. A symbol for the inverter is shown in FIG. 3B. Because of the electrical isolation of the drive from the sense terminals, the requirement that the upper PET turns on with opposite drive sense to that of the lower PET is accomplished straightforwardly via the drive connections. The convenience of unidirectional poling is maintained, while the equivalent of p-channel and n-channel FET's are implemented just by the sense of drive connections.

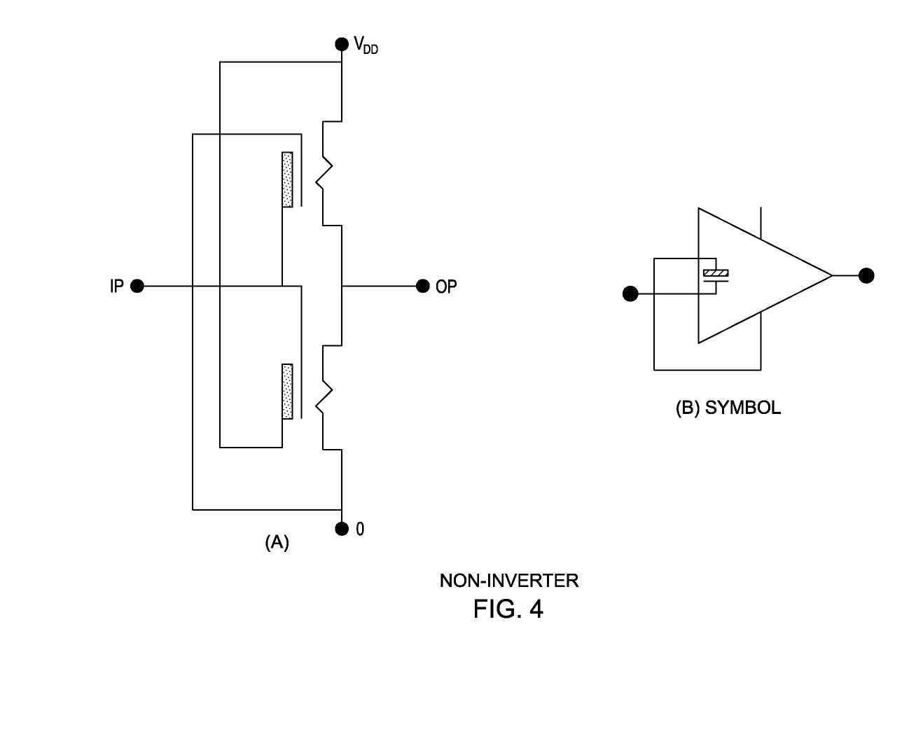

FIG. 4A shows a non-inverting buffer achieved by simply interchanging the input terminals and preserving the polarity with respect to poling by connecting the other terminal to ground or VDD as appropriate. A symbol for the non-inverter is shown in FIG. 4B. This configuration is not possible with 3-terminal PET devices and may be extended to create AND, OR or XOR type circuits. The non-inverting buffer and logic circuits not only can simplify the logic but also eliminate the Miller capacitance between output and input allowing for increased speed and reduced power dissipation.

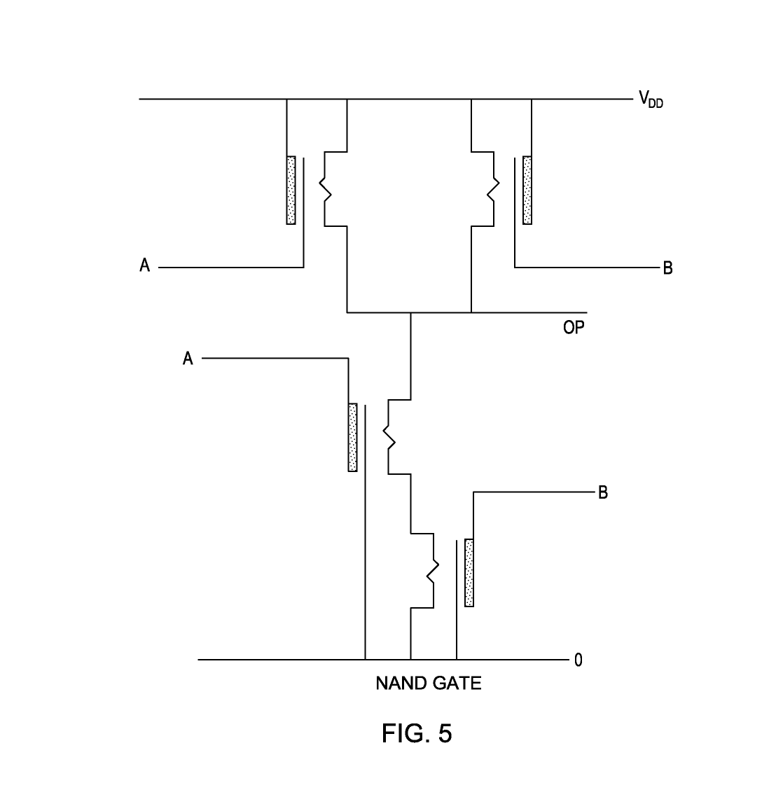

FIG. 5 shows a 4-NAND gate, again broadly similar in design to the CMOS circuit. As with the inverter, the convenience of unidirectional poling is maintained, while the equivalent of p-channel FET's (top 2 PET's) and n-channel FET's (bottom 2 PET's) are implemented just by the sense of drive connections. This circuit is more capable than the CMOS NAND gate since now all of the series-tree inputs can be referenced to ground and problems of gate-voltage degeneration due to an off-ground source terminal are circumvented. To avoid such problems in CMOS a parallel connected pair of n and p-FETs are often used with complementary inputs (pass gate) but this can be substituted by a single 4-terminal PET.

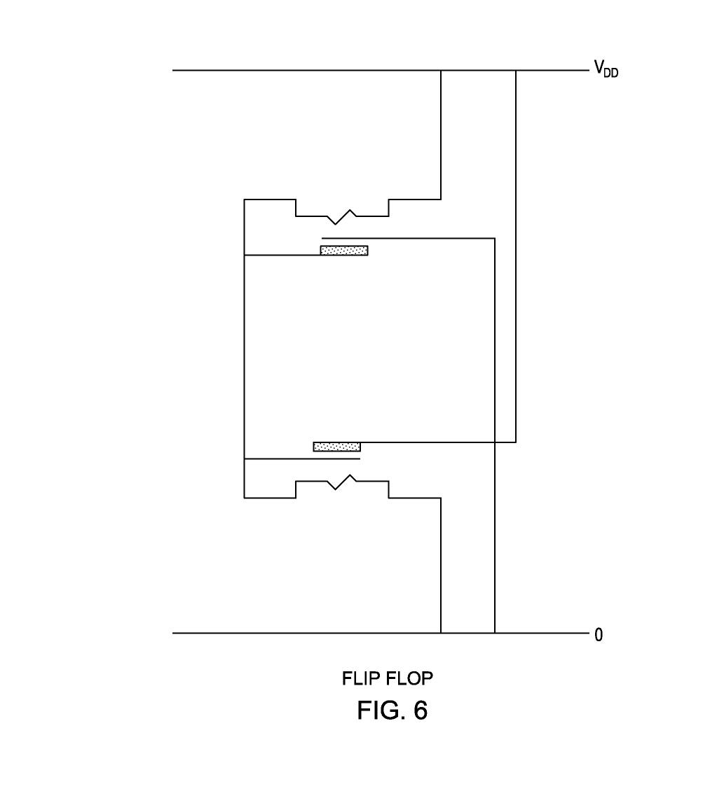

FIG. 6 shows a two transistor flip-flop implemented with 4-terminal PETs, a circuit available in piezotronics but not in CMOS, where the simplest flip-flop involves 4 transistors.

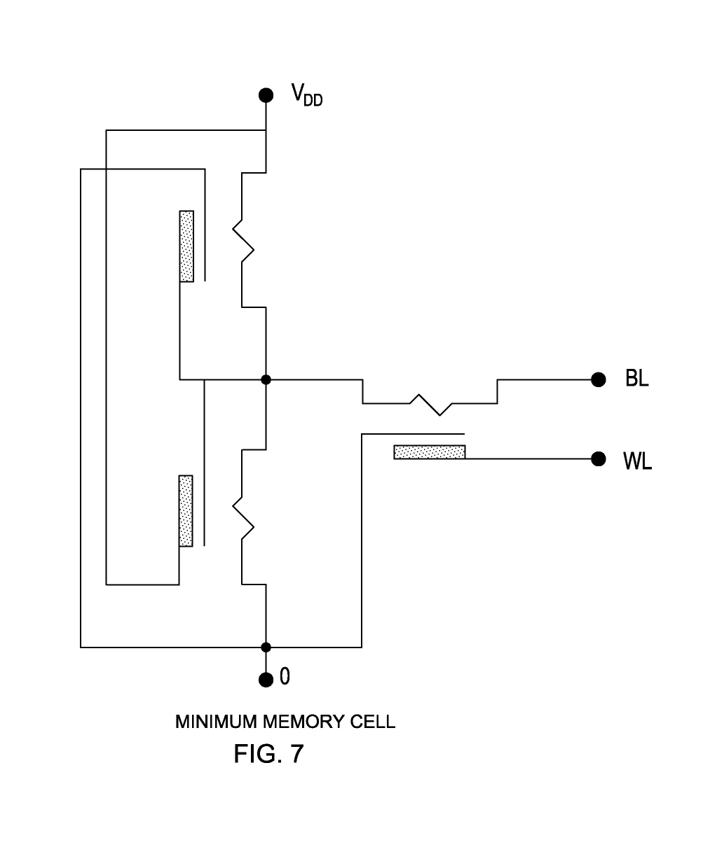

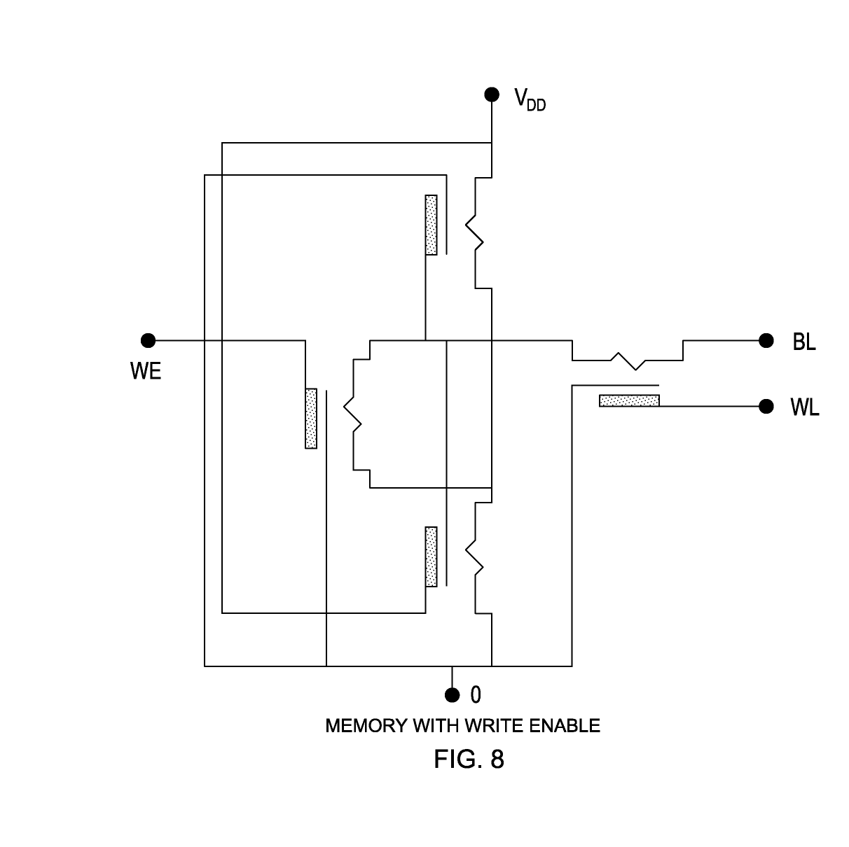

The simplest complete memory cell, using three transistors, is shown in FIG. 7 where, once again, the isolated input of the 4-terminal PET avoids inversion of the input polarity of the series device, which occurs in the 3-terminal PET version of this circuit during write operation. This compares with the 6-transistor CMOS SRAM cell. Ease of writing the cell is greatly enhanced with an additional, fourth, transistor (FIG. 8), breaking the feedback path, where full use is made of the isolated-gate capability. This compares with 8-transistor CMOS latches with the extra transistors added to distinguish write and read paths.

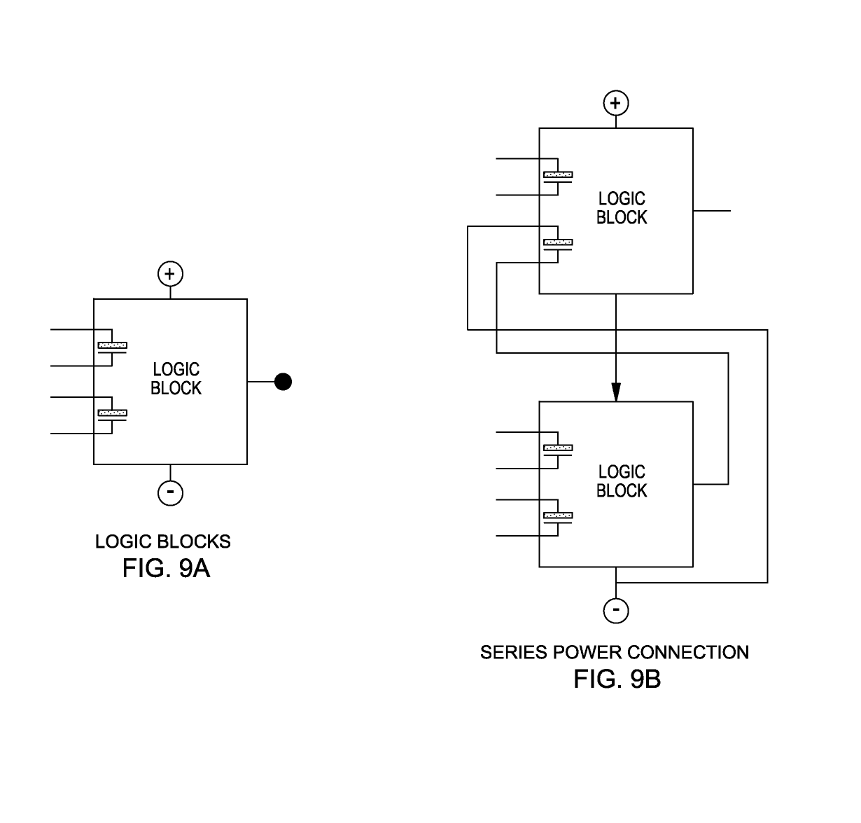

Logic blocks are groups of logic elements. Logic blocks using 4-terminal PETs, as illustrated in FIG. 9A, may have input and output terminals tied to different common-mode voltage references. Indeed, each pair of input terminals may be referenced to a different voltage. This allows for system configurations very difficult and costly to realize in 3-terminal PET implementations. For instance, in FIG. 98, two such blocks of logic are placed in series. In one exemplary embodiment, the output of one logic block may be used as the input for the second logic block. The two circuits share the same power supply current, and with careful load balancing, may divide the power supply voltage between them. Isolated inputs allow easy communication between the two blocks. The impedance of the combination is four times larger than an equivalent parallel combination. Supplying large amounts of power at very low voltages is very difficult and the 4-terminal PET, in an extension of the above example, allows one to transform the load to higher voltages and lower currents.

### Method of Manufacturing a 4-Terminal PET:

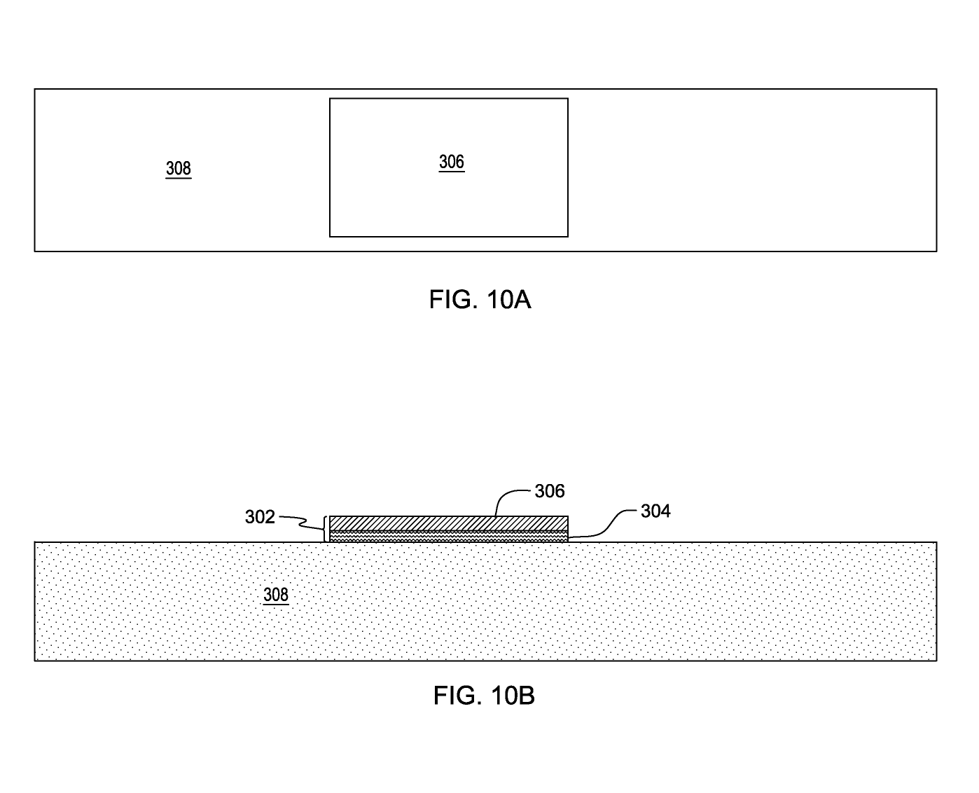

FIGS. 10 through 26 illustrate a method of forming a 4-terminal PET such as that shown in FIG. 2A. In each of FIGS. 10 through 26, the “A” Figure depicts a top view of the device being fabricated while the “B” Figure depicts a cross-sectional view from the side of the device being fabricated.

Referring first to FIGS. 10A and 10B, a material suitable as the Drive+ electrode 302 is blanket deposited and patterned by a lithographic process utilizing, for example, reactive ion etching (RIE). In the exemplary embodiment as best seen in FIG. 10B, two films, STO 304 and SRO 306 may be sequentially deposited and patterned to form the Drive+ electrode 302. The STO 304 creates a substrate upon which the SRO 306 may be deposited epitaxially. The STO 304 does not contribute materially to the conductivity of the Drive+ electrode 302. The substrate 308 may be any semiconductor substrate as discussed above. In other exemplary embodiments, the drive+ electrode 302 may consist of only one layer of material.

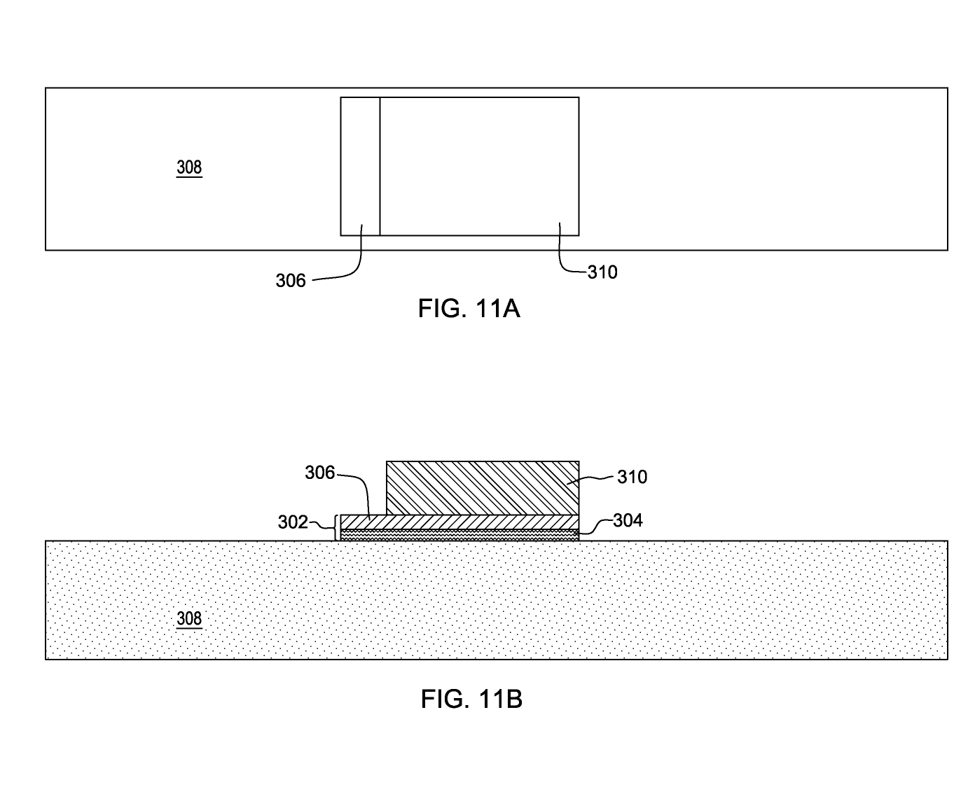

Referring now to FIGS. 11A and 11B, a PE film is blanket deposited and then lithographically patterned and etched by a process such as RIE to form PE material 310. Poling of the PE material 310 may be done subsequently by applying a voltage and heat to the PE material 310.

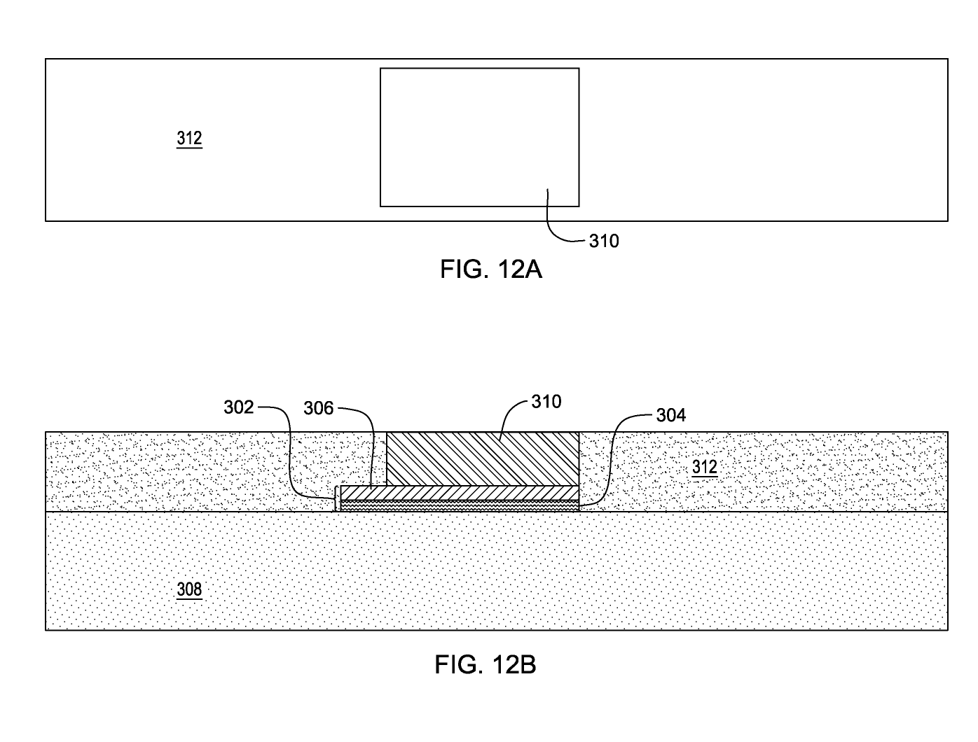

Thereafter, as shown in FIGS. 12A and 12B, amorphous silicon 312 may be deposited and then planarized by a chemical-mechanical polishing (CMP) process, stopping on the PE material 310.

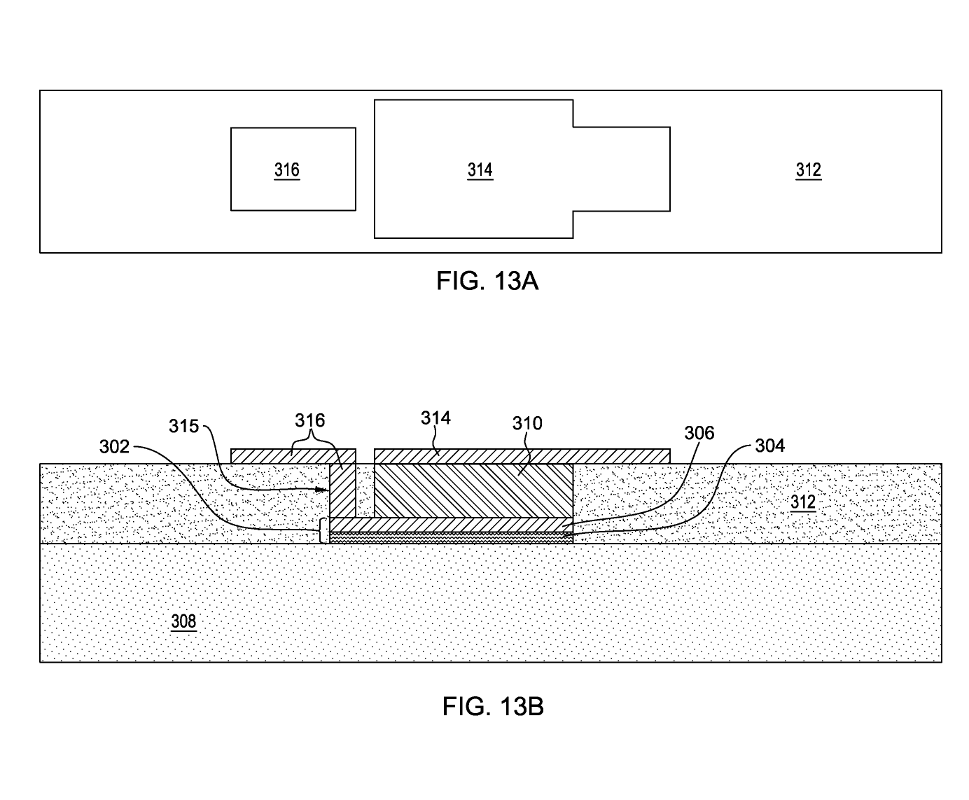

A via opening 315 is then formed in the amorphous silicon 312 adjacent to but spaced from the PE material 310. Subsequently, a suitable metal is blanket deposited and patterned to form the Drive− electrode 314 and via and wiring line 316 connecting to the Drive+ electrode 302 as shown in FIGS. 13A and 13B. The metal may be any of the electrode materials described above.

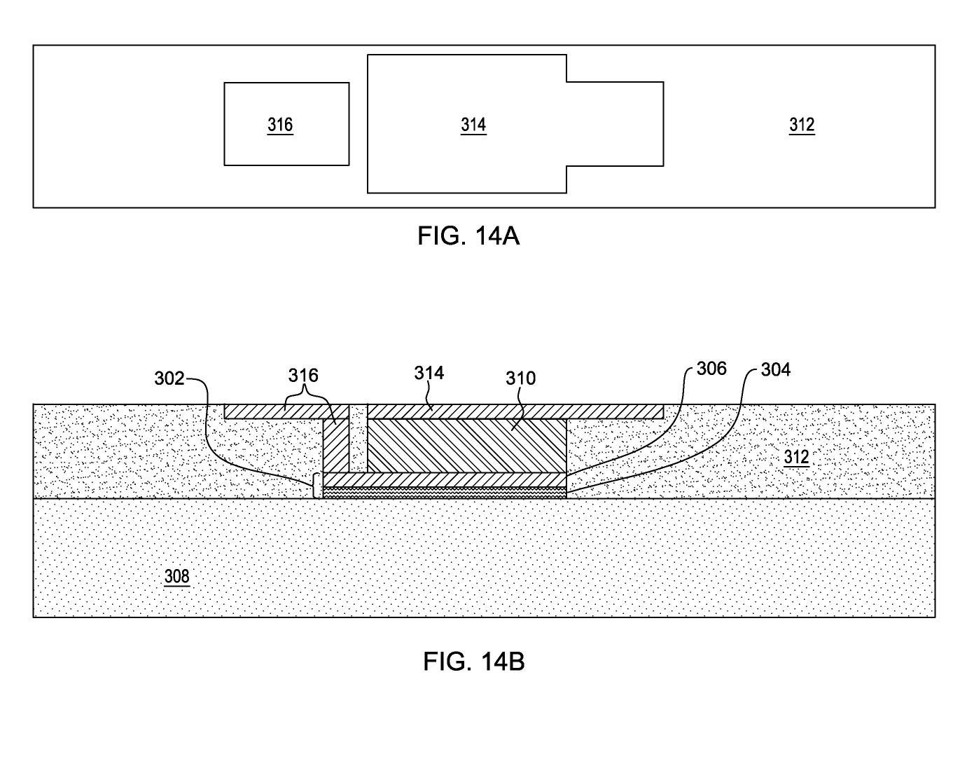

Referring now to FIGS. 14A and 14B, additional amorphous silicon 312 is deposited and planarized by a CMP process, stopping on the Drive− electrode 314 and wiring line 316.

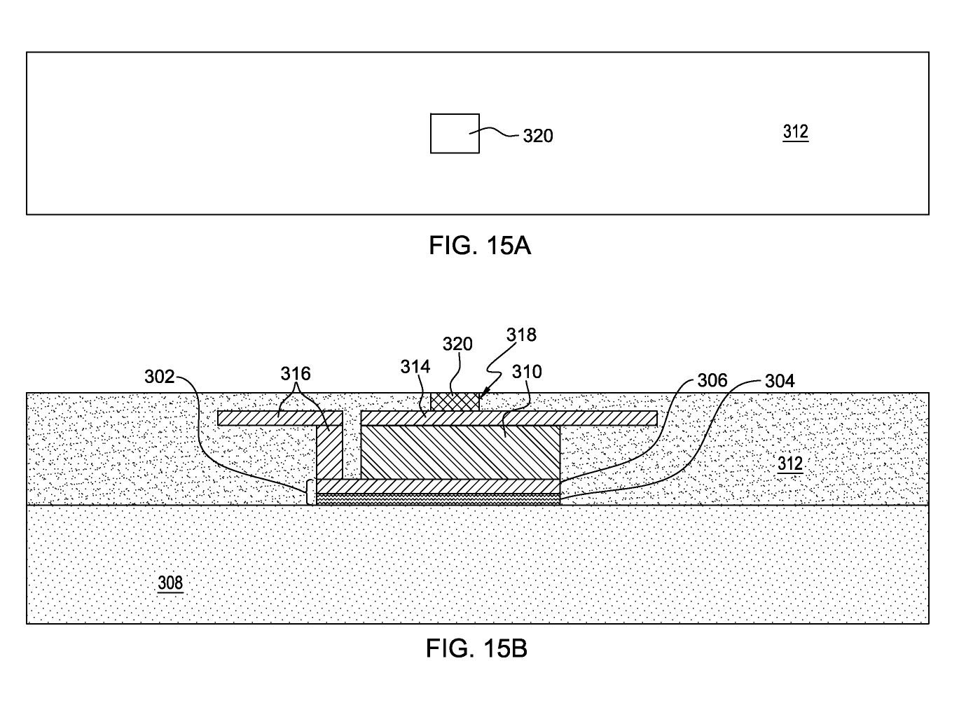

Additional amorphous silicon 312 is deposited and a via opening 318 is formed to expose the Drive− electrode 314. An insulator film is then blanket deposited and fills the via opening 318 to form the insulator 320. The insulator film 320 may be planarized by a CMP process, stopping on the amorphous silicon 312, as shown in FIGS. 15A and 15B.

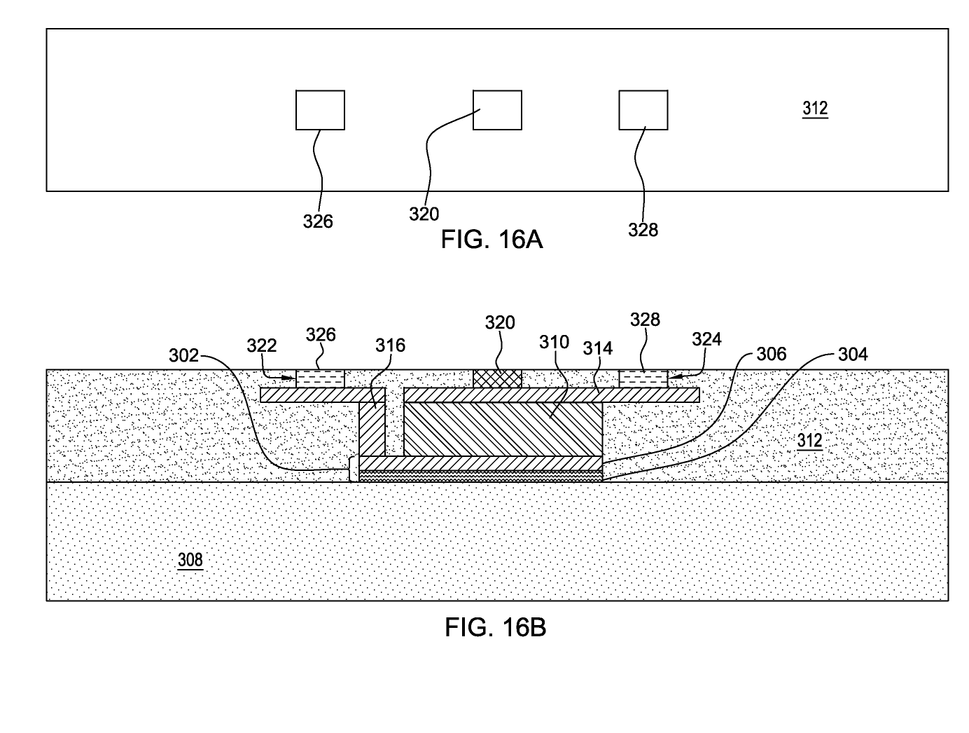

In FIGS. 16A and 16B, a via opening 322 is opened to expose wiring line 316 and via opening 324 is opened to expose Drive− electrode 314. The insulator 320 is blocked and then metal is blanket deposited to fill the via openings 322, 324 to form via 326 in contact with wiring line 316 and via 328 in contact with Drive− electrode 314. Any of the electrode metals described above may be used herein. After deposition of the metal for vias 326, 328, a CMP process may be performed, stopping on the amorphous silicon 312.

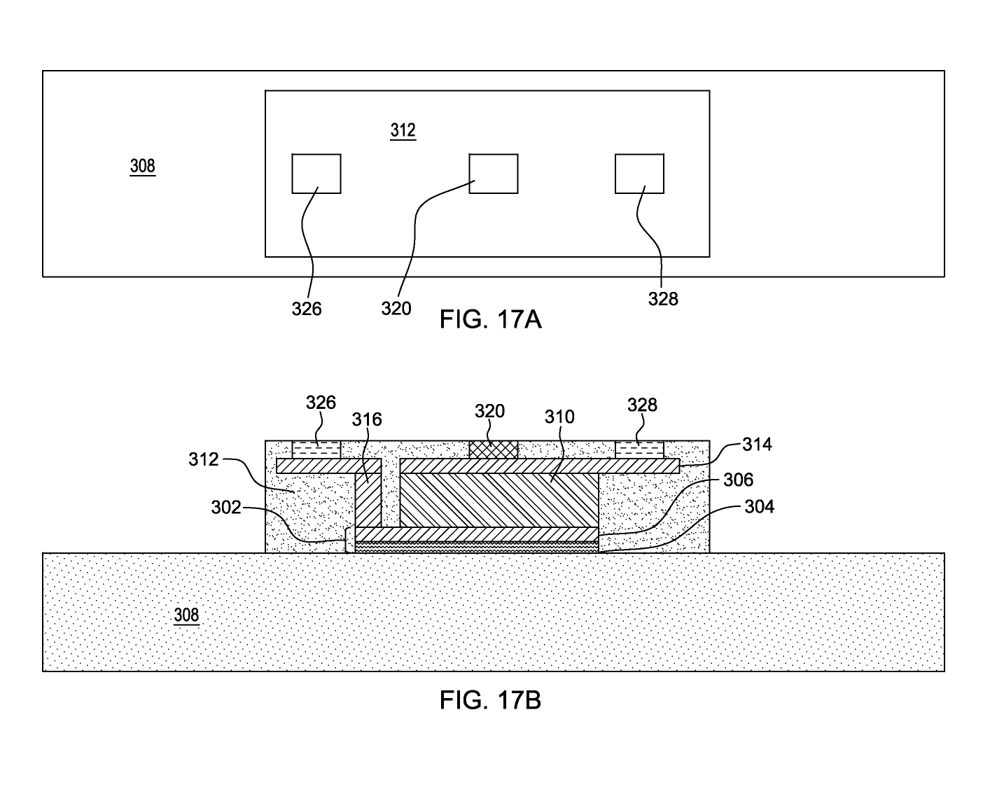

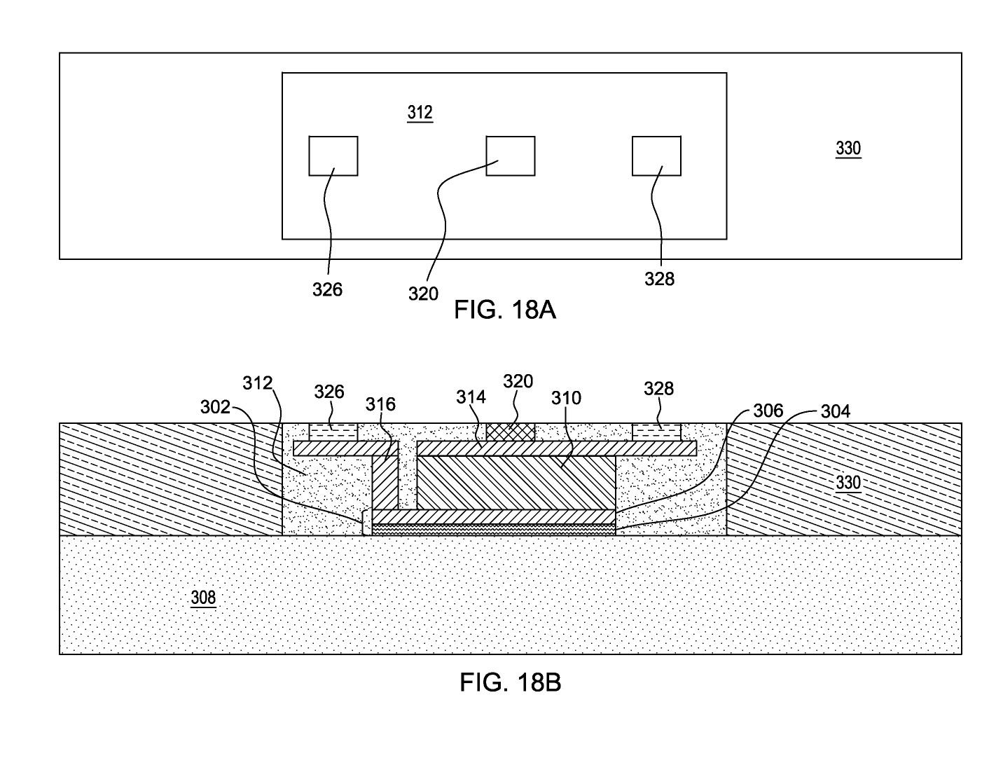

After a RIE process to remove the excess of amorphous silicon 312, as shown in FIGS. 17A and 17B, high yield strength material 330 is blanket deposited and planarized by a CMP process, stopping on the amorphous silicon 312, as shown in FIGS. 18A and 18B.

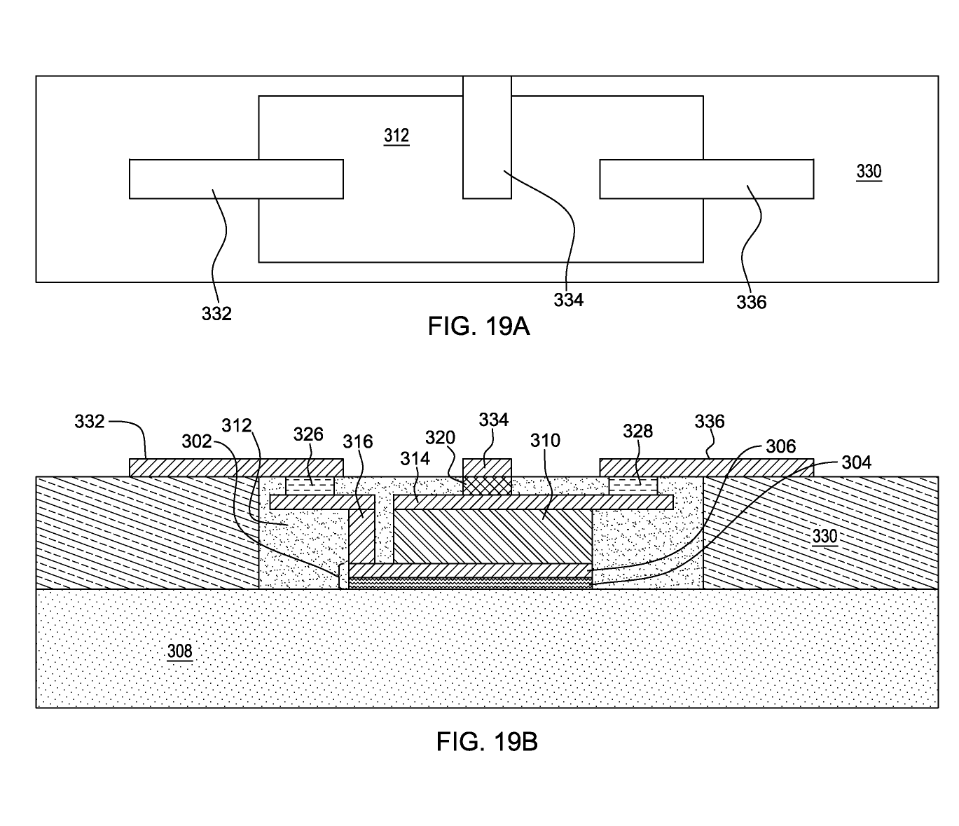

Additional metallization is then deposited and patterned by a RIE process as shown in FIGS. 19A and 19B. This patterned metallization forms wiring lines 332, 334 and 336. Wiring line 332 is in contact with via 326, wiring line 316 and Drive+ electrode 302 while wiring line 336 is in contact with via 328 and Drive− electrode 314. Wiring line 334 will form the Sense 1 electrode for contact with a PR material to be deposited hereafter.

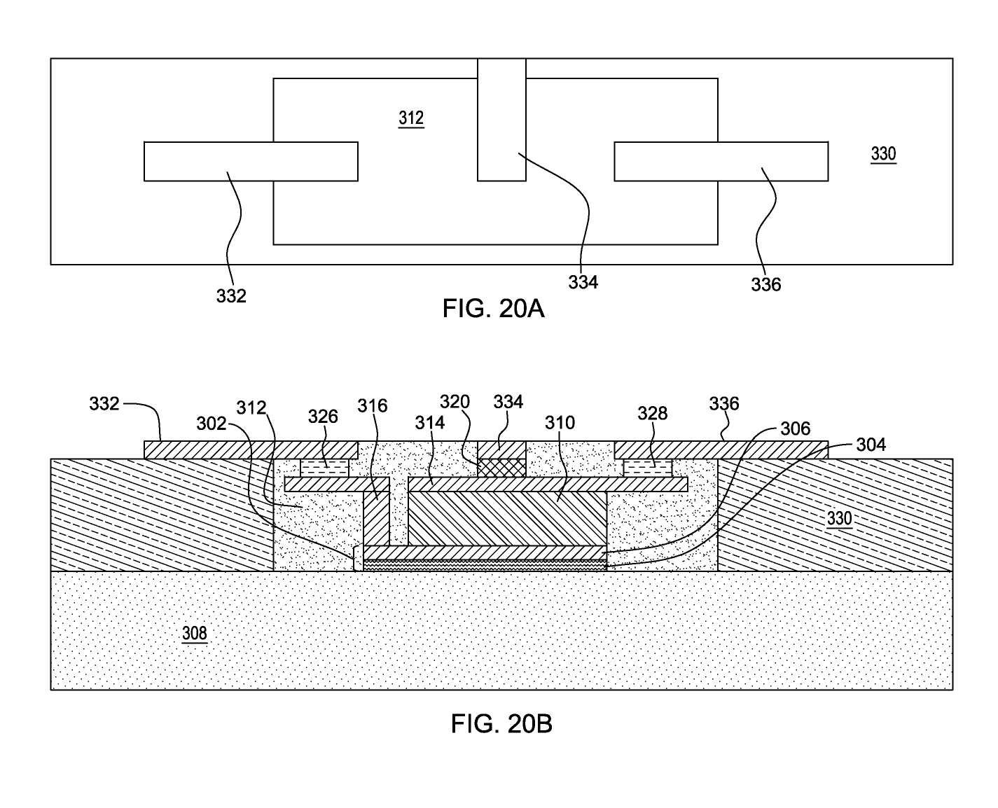

Additional amorphous silicon 312 is deposited and then planarized by a CMP process as shown in FIGS. 20A and 20B. There may be a mask or blocking material present (not shown) so that the additional amorphous silicon 312 is confined to the area where it was previously deposited. The mask or blocking material may then be removed after planarization.

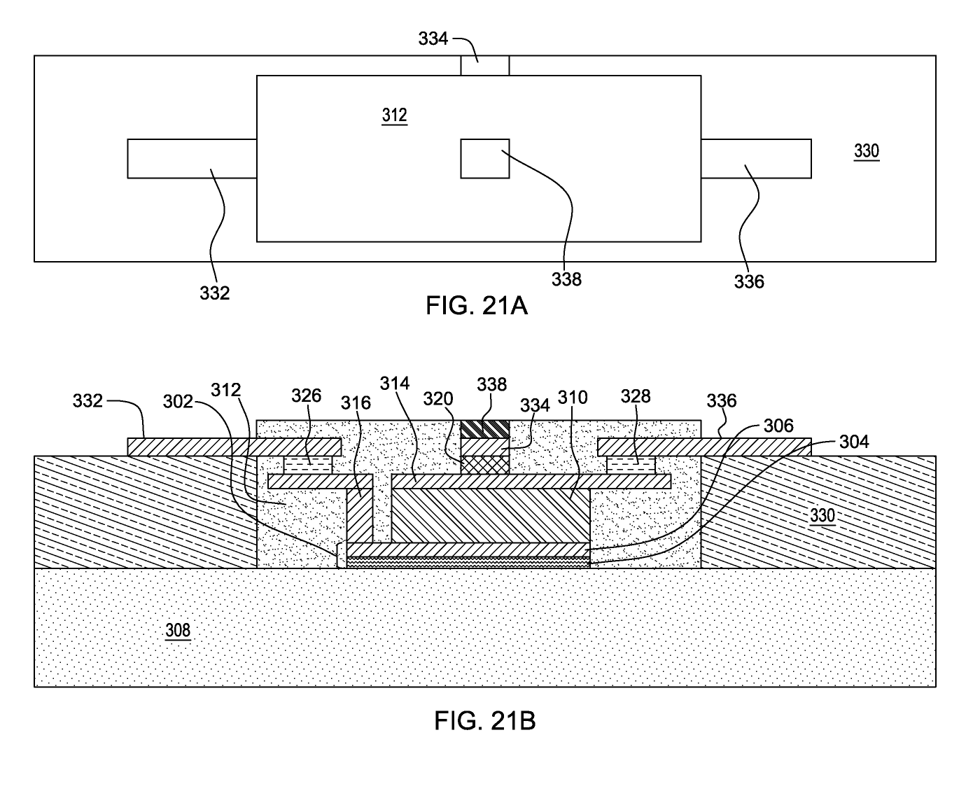

Referring now to FIGS. 21A and 21B, a PR material is deposited and patterned to form PR material 338. Thereafter, additional amorphous silicon 312 is deposited and planarized by a CMP process. There may be a mask or blocking material present (not shown) so that the additional amorphous silicon 312 is confined to the area where it was previously deposited. The mask or blocking material may then be removed after planarization.

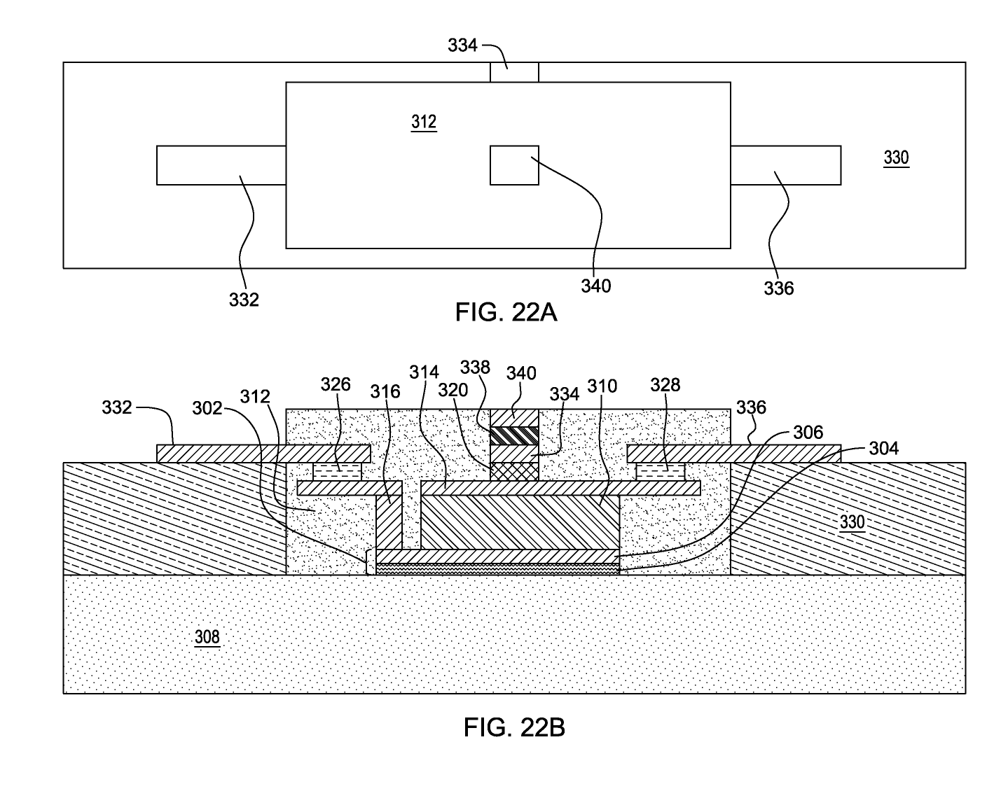

Referring now to FIGS. 22A and 22B, metal is deposited and patterned to form the Sense 2 electrode 340. Thereafter, additional amorphous silicon 312 is deposited and planarized by a CMP process. Again, there may be a mask or blocking material present (not shown) so that the additional amorphous silicon 312 is confined to the area where it was previously deposited. The mask or blocking material may then be removed after planarization.

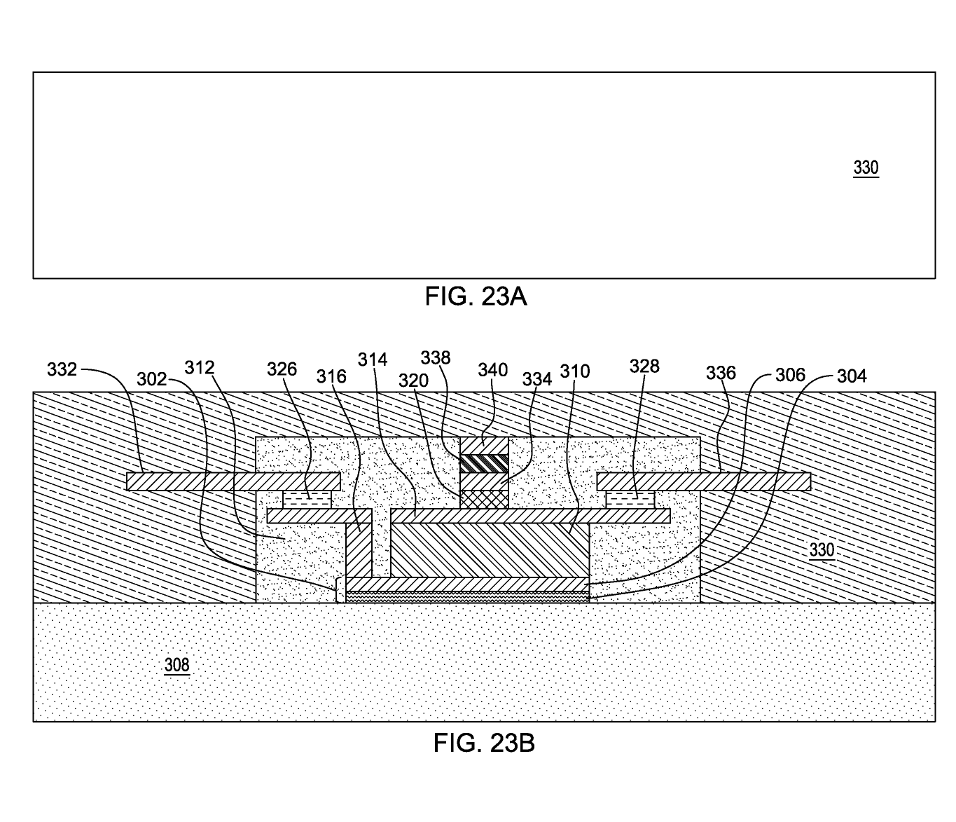

Additional high yield strength material 330 is blanket deposited and planarized by a CMP process to result in the structure shown in FIGS. 23A and 23B.

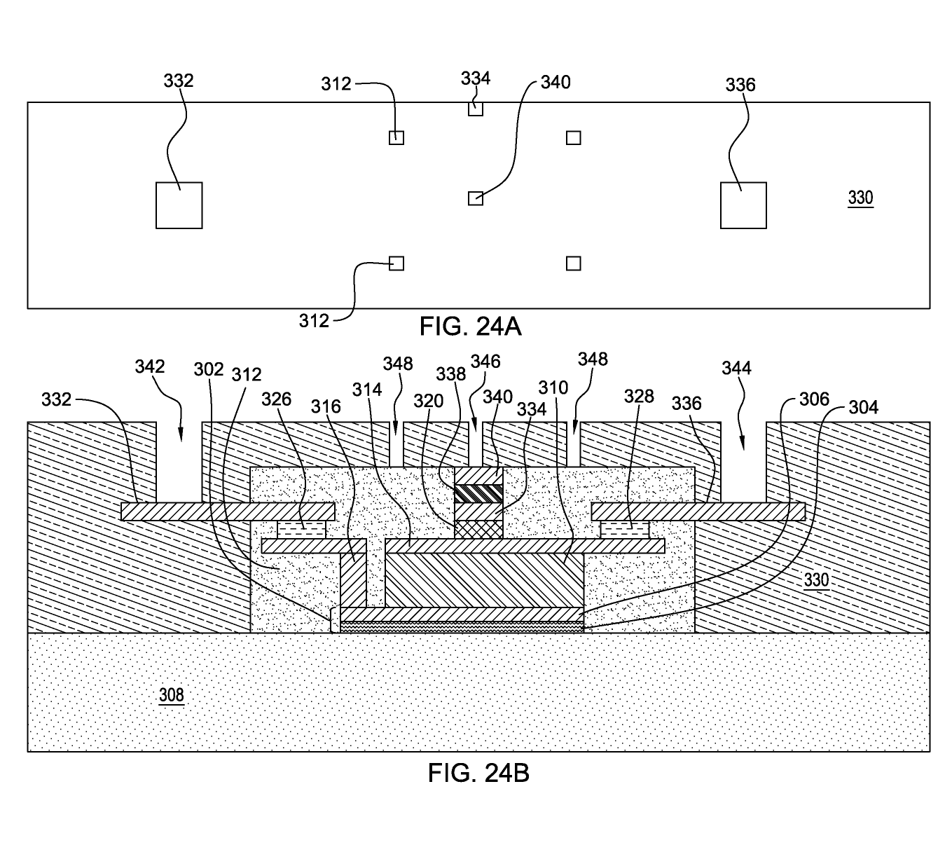

As shown in FIGS. 24A and 24B, via openings in the high yield strength material 330 may be formed by a RIE process. Via opening 342 exposes metallization 332 which is in contact with Drive+ electrode 302, via opening 344 exposes metallization 336 which is in contact with Drive− electrode 314 and via opening 346 exposes Sense 2 electrode 340. Not shown in FIG. 24B would be another via opening for exposing Sense 1 electrode 334; however, Sense 1 electrode 334 may be seen through high yield strength material 330 in FIG. 24A. FIGS. 24A and 24B additionally show via openings 348 which expose the underlying amorphous silicon 312. In a subsequent process step, the amorphous silicon 312 may be removed through via openings 348.

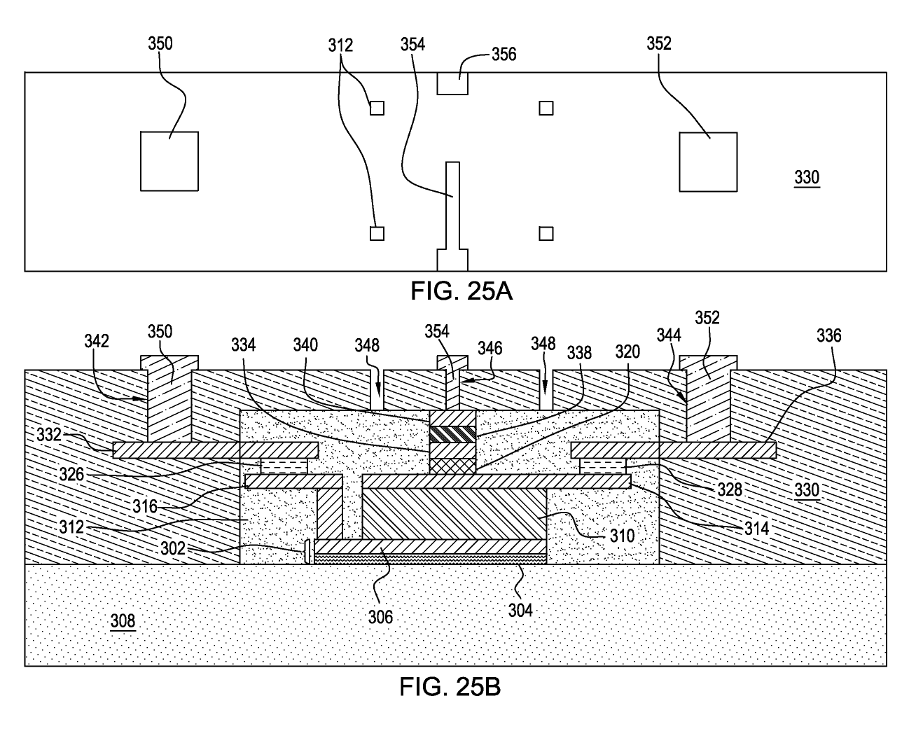

Referring to FIGS. 25A and 25B, contact 350 has been formed in via opening 342, contact 352 has been formed in via opening 344 and contact 354 has been formed in via opening 346. In a similar manner, contact 356 would be formed to contact Sense 1 electrode 334.

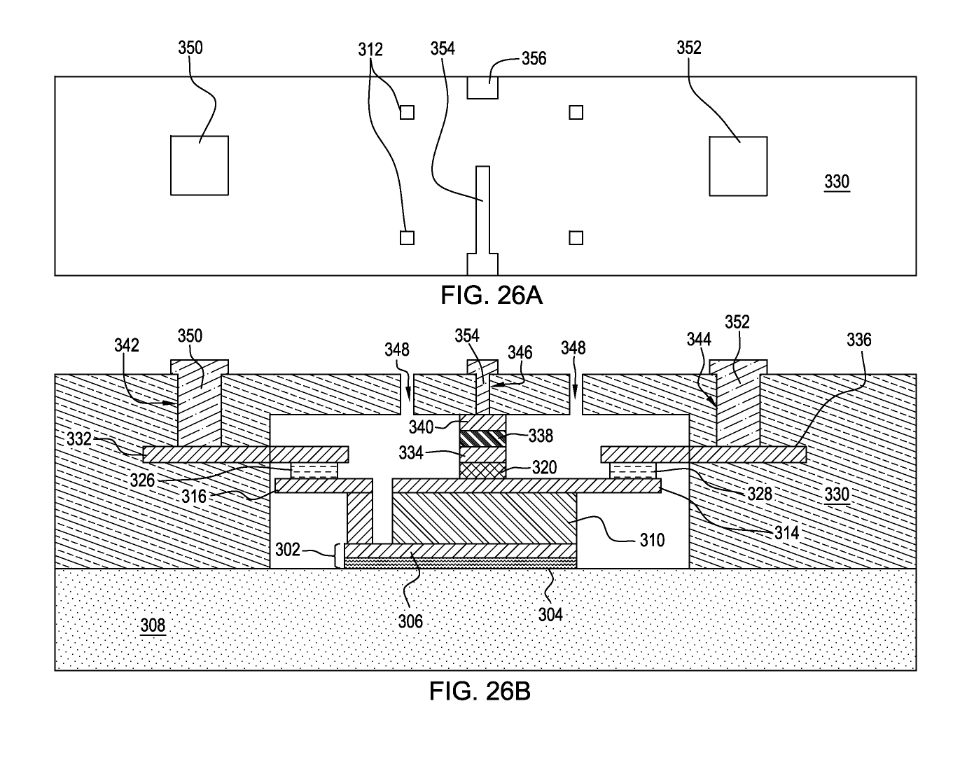

The amorphous silicon is preferably removed from the 4-terminal PET. This may occur by exposing the amorphous silicon 312 to a vapor of xenon difluoride (XeF₂) through via openings 348. Xenon difluoride is an etching process which uses an exposure of the xenon difluoride gas in a closed vacuum system and is very selective to amorphous silicon which makes removal of the amorphous silicon very effective. The resulting structure is shown in FIGS. 26A and 26B.

Subsequently, the semiconductor structure shown in FIGS. 26A and 26B, including the 4-terminal PET would undergo conventional semiconductor middle of the line and back end of the line processing to form semiconductor devices on the semiconductor substrate 308

It will be apparent to those skilled in the art having regard to this disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A 4-terminal piezoelectronic transistor (PET) comprising:
a piezoelectric (PE) material disposed between first and second electrodes;
an insulator material disposed on the second electrode;
a third electrode disposed on the insulator material; and
a piezoresistive (PR) material disposed between the third electrode and a fourth electrode;
wherein an applied voltage across the first and second electrodes causing a pressure from the PE material to be applied to the PR material through the insulator material, the electrical resistance of the PR material being dependent upon the pressure applied by the PE material.

2. The 4-terminal PET of claim 1 wherein the first and second electrodes and PE material are isolated from the third and fourth electrodes and the PR material by the insulator material.

3. The 4-terminal PET of claim 1 wherein the PR material is highly resistive when there is no pressure being applied by the PE material.

4. The 4-terminal PET of claim 1 wherein the PR is conductive when pressure is applied by the PE material.

5. The 4-terminal PET of claim 1 wherein the PE material disposed between the first and second electrodes forming a first stack of materials and the PR material between third and fourth electrodes and the insulator material forming a second stack of materials and further comprising a high yield strength material surrounding the first and second stacks of material, the high yield material confining the pressure from the PE material to be directed to the PR material.

6. The 4-terminal PET of claim 5 further comprising a gap between the first and second stacks of material and the high yield strength material.

7. The 4-terminal PET of claim 5 wherein the high yield strength material selected from the group consisting of silicon dioxide (SiO2) and silicon nitride (Si3N4).

8. The 4-terminal PET of claim 1 wherein the PE material disposed between the first and second electrodes forming a first stack of materials and the PR material between third and fourth electrodes and the insulator material forming a second stack of materials such that the first stack of materials has a larger cross sectional dimension than the second stack of materials.

9. The 4-terminal PET of claim 1 wherein the PE material is selected from the group consisting of PMN-PT (lead magnesium niobate-lead titanate), PZN-PT (lead zinc niobate-lead titanate), PZT (lead zirconate titanate) and other piezoelectric materials.

10. The 4-terminal PET of claim 1 wherein the PR material is selected from the group consisting of samarium selenide (SmSe), thulium telluride (TmTe), nickel disulfide/diselenide (Ni(SxSe1-x)₂), vanadium oxide (V2O3), calcium ruthenium oxide (Ca₂RuO4) and other piezoresistive materials.

11. A logic device comprising a plurality of 4-terminal piezoelectronic transistor (PET) devices coupled together to form the logic device, each 4-terminal PET comprising:
a piezoelectric (PE) material disposed between first and second electrodes;
an insulator material disposed on the second electrode;
a third electrode disposed on the insulator material; and
a piezoresistive (PR) material disposed between the third electrode and a fourth electrode;
wherein an applied voltage across the first and second electrodes causing a pressure from the PE material to be applied to the PR material through the insulator material, the electrical resistance of the PR material being dependent upon the pressure applied by the PE material and wherein the first and second electrodes are electrically isolated from the third and fourth electrodes.

12. The logic device of claim 11 wherein the 4-terminal PETs are coupled together to form an inverter.

13. The logic device of claim 11 wherein the 4-terminal PETs are coupled together to form a non-inverter.

14. The logic device of claim 11 wherein the 4-terminal PETs are coupled together to form a NAND gate.

15. The logic device of claim 11 wherein the 4-terminal PETs are coupled together to form a flip-flop.

16. The logic device of claim 11 wherein the 4-terminal PETs are coupled together to form a memory cell.

17. The logic device of claim 11 wherein the 4-terminal PETs are coupled together to form a memory cell with write enable.

18. The logic device of claim 11 wherein the 4-terminal PETs are coupled together to form a logic block comprising a plurality of logic elements.

19. The logic device of claim 18 wherein there are a plurality of logic blocks connected in series.

20. The logic device of claim 19 wherein the output of one logic block is the input for a second logic block connected in series.

21. A method of forming a 4-terminal piezoelectronic transistor (PET) comprising:
forming a first stack of materials comprising:
forming a first electrode;
forming a piezoelectric (PE) material over the first electrode;
forming a second electrode over the PE material; and
forming a second stack of materials comprising:
forming an insulator material over the second electrode;
forming a third electrode over the insulator material;
forming a piezoresistive (PR) material over the third electrode; and
forming a fourth electrode over the PR material.

22. The method of claim 21 further comprising forming a high yield strength material over the first and second stacks of materials.

23. The method of claim 21 further comprising:
forming amorphous silicon over the first and second stacks of materials; and
forming a high yield material over the amorphous silicon.

24. The method of claim 23 further comprising:
forming at least one opening in the high yield material to expose the amorphous silicon; and
applying an etchant to remove the amorphous silicon between the first and second stacks of materials and the high yield material so as to leave a gap between the first and second stacks of materials and the high yield material.

25. The method of claim 21 wherein the first stack of materials having a larger cross sectional dimension than the second stack of materials.
